(19) United States
(12) Patent Application Publication
(10) Pub. No.: US 2023/0408652 A1
(43) Pub. Date: Dec. 21, 2023

(54) LIGHT EMISSION DEVICE AND DISTANCE MEASUREMENT DEVICE

(71) Applicant: Panasonic Intellectual Property Management Co., Ltd., Osaka (JP)

(72) Inventors: Hirotaka Ueno, Osaka (JP); Kiyoshi Morimoto, Osaka (JP); Keisuke Kojima, Shizuoka (JP)

(21) Appl. No.: 18/241,762

(22) Filed: Sep. 1, 2023

Related U.S. Application Data
(63) Continuation of application No. PCT/JP2022/006241, filed on Feb. 16, 2022.

(30) Foreign Application Priority Data
Mar. 5, 2021 (JP) 2021-035794

(51) Int. Cl. G01S 7/484; G01S 7/481; G01R 15/04; G01S 17/10; G01R 19/00

(52) U.S. Cl. CPC G01S 7/484; G01S 7/4814; G01R 15/04; G01S 17/10; G01R 19/0084

(57) ABSTRACT

A light emission device includes: a laser light source; an electric storage element for supplying a drive current to the laser light source; a plurality of switch elements connected in series to the laser light source; and an electrical element placed at least between a ground and an input part, for a switch opening/closing signal, of the switch element to which another one of the switch elements is connected on a downstream side, and configured to guide noise having a high level exceeding a voltage level of the switch opening/closing signal, to the ground.

### CROSS REFERENCE TO RELATED APPLICATION

This application is a continuation of International Application No. PCT/JP2022/006241 filed on Feb. 16, 2022, entitled “LIGHT EMISSION DEVICE AND DISTANCE MEASUREMENT DEVICE”, which claims priority under 35 U.S.C. Section 119 of Japanese Patent Application No. 2021-035794 filed on Mar. 5, 2021, entitled “LIGHT EMISSION DEVICE AND DISTANCE MEASUREMENT DEVICE”. The disclosures of the above applications are incorporated herein by reference.

### BACKGROUND OF THE INVENTION

### Field of the Invention

The present invention relates to a light emission device that emits pulsed light, and a distance measurement device that measures the distance to an object using the pulsed light emitted from the light emission device.

### Description of Related Art

To date, a distance measurement device that measures the distance to an object using pulsed laser light whose intensity changes in a pulse peak has been known. In this type of distance measurement device, for example, the distance to an object is measured on the basis of the time difference between the timing when laser light is emitted and the timing when reflected light, from the object, of the laser light is received. Japanese Laid-Open Patent Publication No. H07-229967 describes this type of distance measurement device.

When pulsed laser light is emitted as described above, a laser light source is controlled such that the amount of laser light per pulse satisfies the eye-safety criterion. However, if an abnormality occurs in a control circuit for the laser light source, this control can no longer be performed properly.

Japanese Laid-Open Patent Publication No. 2003-124564 describes a configuration in which the amount of light emitted from a laser light source is monitored by a photosensor for monitoring. In this configuration, drive of the laser light source is stopped when the output of the photosensor for monitoring exceeds a predetermined level.

As a configuration for causing a laser light source to emit pulsed light, a configuration in which a switch element is connected in series to the laser light source and this switch element is made conductive during the period of pulsed light emission can be used. However, in this configuration, if a failure occurs in the switch element, pulsed light emission of the laser light source is no longer performed properly.

### SUMMARY OF THE INVENTION

A first aspect of the present invention is directed to a light emission device. The light emission device according to this aspect includes: a laser light source; an electric storage element for supplying a drive current to the laser light source; a plurality of switch elements connected in series to the laser light source; and an electrical element placed at least between a ground and an input part, for a switch opening/closing signal, of the switch element to which another one of the switch elements is connected on a downstream side, and configured to guide noise having a high level exceeding a voltage level of the switch opening/closing signal, to the ground.

In the light emission device according to this aspect, since the plurality of switch elements are connected in series to the laser light source, even if a short circuit occurs in any of the switch elements, the laser light source can be caused to properly emit pulsed light by another one of the switch elements.

Here, in the case where a plurality of switch elements are connected in series to a laser light source, when the switch elements are opened, a connection portion between two adjacent switch elements is brought into a floating state. Therefore, noise is more likely to be superimposed on an input part of the switch element on the laser light source side. Therefore, if a time lag occurs between switch opening/closing signals inputted to these switch elements, high-level noise is generated in the input part of the switch element on the laser light source side out of these two switch elements by ringing caused by extra electric charge in the electric storage element being passed back and forth between the electric storage element and the switch element. If this noise exceeds the rating of the switch element, a failure may occur in the switch element.

On the other hand, in the light emission device according to this aspect, as described above, the electrical element which guides, to the ground, high-level noise generated in the input part, to which the switch opening/closing signal is inputted, of at least the switch element to which another switch element is connected on the downstream side, is placed. Therefore, noise due to the above-described ringing is guided to the ground, and noise exceeding the rating is inhibited from being generated in the input part. Accordingly, a failure of the switch element due to noise can be suppressed.

Thus, in the light emission device according to this aspect, pulsed light emission of the laser light source can be performed more properly while failures of the switch elements are suppressed.

A second aspect of the present invention is directed to a distance measurement device. The distance measurement device according to this aspect includes: the light emission device according to the first aspect; a projection optical system configured to project pulsed light emitted from the light emission device, to a target region; and a light receiver configured to receive reflected light, from an object, of the pulsed light.

Since the distance measurement device according to this aspect includes the light emission device according to the first aspect, pulsed light emission of the laser light source can be performed more properly while failures of the switch elements are suppressed. Thus, the reliability of the distance measurement device can be increased.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a block diagram showing a configuration of a distance measurement device according to Embodiment 1;

FIG. 2 is a circuit diagram showing a configuration of a light emission device according to a reference example;

FIG. 3A and FIG. 3B are respectively time charts of two switch elements showing ON/OFF states when a short circuit occurs in one of the switch elements according to the reference example;

FIG. 3C is a time chart showing a drive current of a laser light source in the case of FIG. 3A and FIG. 3B;

FIG. 3D is a time chart showing an ON/OFF state of a switch element when a short circuit occurs in the switch element, according to a comparative example;

FIG. 3E is a time chart showing a drive current of a laser light source in the case of FIG. 3D;

FIG. 4 is a circuit diagram showing a configuration of a light emission device according to Embodiment 1;

FIG. 5A is a graph showing the simulation results of a voltage generated in an input part of each switch element when there is no time lag between drive signals respectively inputted to the two switch elements according to the reference example;

FIG. 5B is a graph showing the simulation results of a voltage generated in the input part of each switch element when there is a time lag between the drive signals respectively inputted to the two switch elements according to the reference example;

FIG. 5C is a graph showing the simulation results of a voltage generated in an input part of each switch element when there is no time lag between drive signals respectively inputted to two switch elements according to Embodiment 1;

FIG. 5D is a graph showing the simulation results of a voltage generated in the input part of each switch element when there is a time lag between the drive signals respectively inputted to the two switch elements according to Embodiment 1;

FIG. 6 is a circuit diagram showing a configuration of a light emission device according to Embodiment 2;

FIG. 7A and FIG. 7B are respectively time charts showing examples of drive signals respectively inputted to two switch elements according to Embodiment 2;

FIG. 7C is a time chart showing a drive current of a laser light source in the case of FIG. 7A and FIG. 7B;

FIG. 8 is a flowchart showing a driver abnormality detection process according to Embodiment 2;

FIG. 9 is a circuit diagram showing a configuration of a light emission device according to Embodiment 3;

FIG. 10A to FIG. 10D are respectively time charts showing the simulation results of drive signals, an applied voltage (drain voltage) of each switch element, a monitoring signal, and a drive current of a laser light source when two switch elements are operating normally, according to Embodiment 3;

FIG. 11A to FIG. 11D are respectively time charts showing the simulation results of a drive signal of a downstream switch element, an applied voltage (drain voltage) of the downstream switch element, a monitoring signal, and a drive current of the laser light source when a short circuit occurs only in an upstream switch element, according to Embodiment 3;

FIG. 12A to FIG. 12D are respectively time charts showing the simulation results of a drive signal of the upstream switch element, an applied voltage (drain voltage) of the upstream switch element, a monitoring signal, and a drive current of the laser light source when a short circuit occurs only in the downstream switch element, according to Embodiment 3;

FIG. 13 is a flowchart showing a switch element abnormality detection process according to Embodiment 3;

FIG. 14 is a block diagram showing a configuration of a light emission device according to Embodiment 3;

FIG. 15 is a block diagram showing a configuration of a light emission device according to a modification of Embodiment 3;

FIG. 16 is a circuit diagram showing a configuration of a light emission device according to Modification 1; and

FIG. 17 is a circuit diagram showing a configuration of a light emission device according to Modification 2.

It should be noted that the drawings are solely for description and do not limit the scope of the present invention by any degree.

### DETAILED DESCRIPTION

Hereinafter, embodiments of the present invention will be described with reference to the drawings.

### Embodiment 1

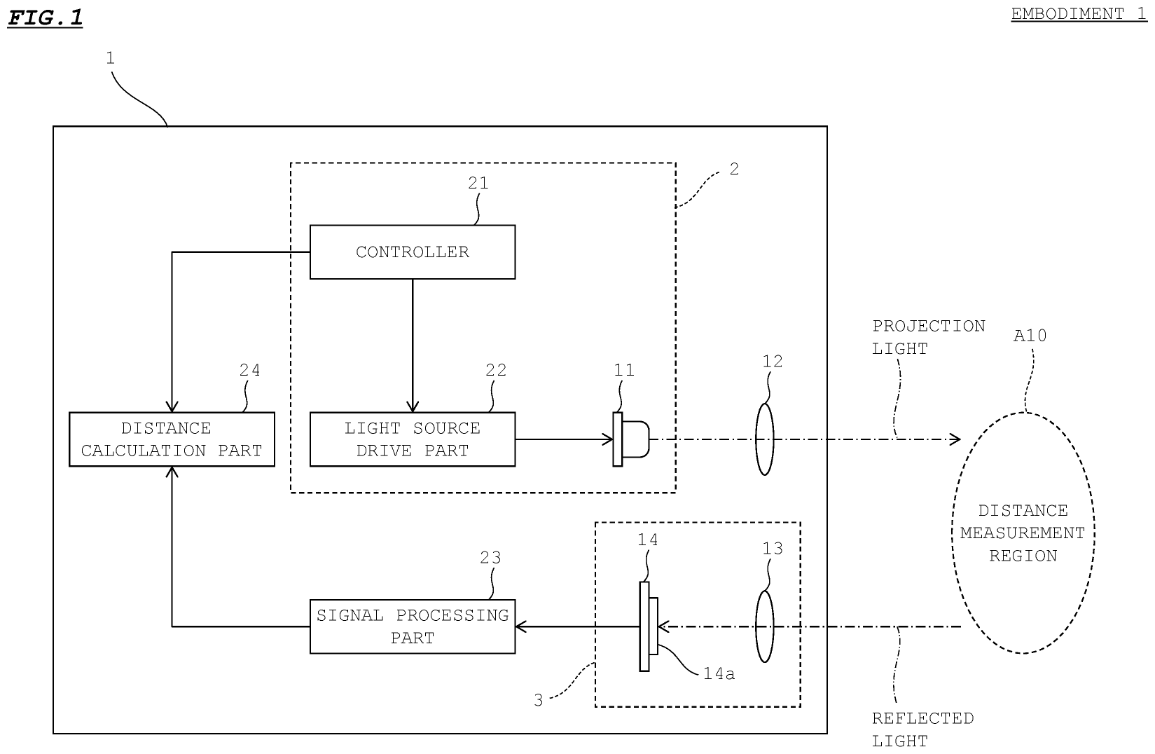

FIG. 1 is a block diagram showing a configuration of a distance measurement device 1. FIG. 1 shows a so-called flash type distance measurement device 1.

The distance measurement device 1 includes a laser light source 11, a projection optical system 12, a receiving optical system 13, and an image sensor 14 as components of an optical system.

The laser light source 11 is composed of a laser diode, for example, and emits laser light (projection light) having a predetermined wavelength. In the case where the distance measurement device 1 is installed in a vehicle, the emission wavelength of the laser light source 11 is set, for example, in the infrared wavelength band (e.g., 905 nm). The emission wavelength of the laser light source 11 can be changed as appropriate according to the usage of the distance measurement device 1. The laser light source 11 may be composed of a plurality of laser diodes. Alternatively, the laser light source 11 may be composed of another laser emitter other than laser diodes.

The projection optical system 12 guides the projection light emitted from the laser light source 11, to a distance measurement region A10 at a predetermined spread angle. The projection optical system 12 projects projection light with a uniform intensity distribution to the distance measurement region A10. The projection optical system 12 may be composed of a single lens or may include a plurality of lenses. The projection optical system 12 may also include a concave mirror or the like.

The receiving optical system 13 collects reflected light of the laser light reflected by an object existing in the distance measurement region A10, onto a light-receiving surface 14a of the image sensor 14. The receiving optical system 13 may be composed of a single lens or may include a plurality of lenses. The receiving optical system 13 may also include a concave mirror or the like.

The image sensor 14 receives the reflected light by a plurality of pixels arranged on the light-receiving surface 14a, and outputs a detection signal corresponding to the intensity of the reflected light received. A large number of pixels are arranged in a matrix on the light-receiving surface 14a. In each pixel, for example, an avalanche photodiode is placed. Another light detection element may be placed in each pixel.

A filter that transmits the wavelength band of the projection light and blocks light in the other wavelength bands may be placed between the receiving optical system 13 and the image sensor 14. Accordingly, unnecessary light having wavelengths different from that of the projection light can be inhibited from being incident on the light-receiving surface 14a of the image sensor 14. In addition, in the case where the laser light source 11 emits infrared light, the image sensor 14 may have detection sensitivity only in the infrared wavelength band. Accordingly, detection of visible light, which is unnecessary light, by the image sensor 14 can be inhibited.

The distance measurement device 1 includes a controller 21, a light source drive part 22, a signal processing part 23, and a distance calculation part 24 as components of a circuitry.

The controller 21 includes an arithmetic processing circuit and a memory, and is composed of, for example, an FPGA, an MPU, a ROM, a RAM, etc. The controller 21 outputs a control signal to the light source drive part 22 to control the laser light source 11 via the light source drive part 22. The light source drive part 22 causes the laser light source 11 to emit pulsed light at a predetermined intensity and pulse width in response to the control signal. The controller 21 also outputs the control signal outputted to the light source drive part 22, to the distance calculation part 24 at the same timing as the output to the light source drive part 22.

The signal processing part 23 performs amplification and noise removal on the detection signal of each pixel outputted from the image sensor 14, and outputs the processed detection signal to the distance calculation part 24.

The distance calculation part 24 is a circuit that includes an arithmetic processing circuit and a memory and performs calculation of a distance. The distance calculation part 24 calculates the distance to a target object in the distance measurement region A10 for each pixel on the basis of the timing when the control signal for pulsed light emission is received from the controller 21 and the timing when the detection signal of each pixel of the image sensor 14 is received from the signal processing part 23. The distance calculation part 24 generates distance image data for one screen (one frame) in which the distance calculated for each pixel is mapped to the position of each pixel, and outputs the generated distance image data to a display part of the distance measurement device 1, an external device to which the distance measurement device 1 is connected, or the like.

In the configuration in FIG. 1, the laser light source 11, the light source drive part 22, and the controller 21 constitute a light emission device 2. Here, the controller 21 controls the distance measurement device 1 as well as the light emission device 2. Also, the receiving optical system 13 and the image sensor 14 constitute a light receiver 3.

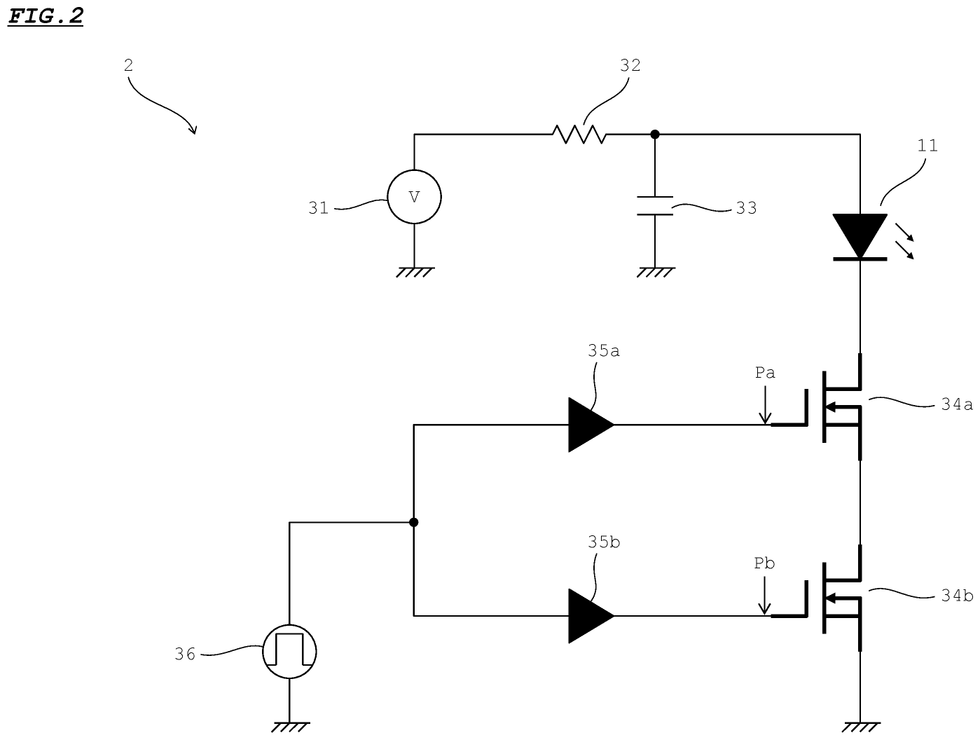

FIG. 2 is a circuit diagram showing a configuration of the light emission device 2 according to a reference example. In FIG. 2, the controller 21 is not shown.

In addition to the laser light source 11 shown in FIG. 1, the light emission device 2 according to the reference example includes a DC power supply 31, a resistor 32, an electric storage element 33, switch elements 34a and 34b, drivers 35a and 35b, and a pulse generation circuit 36 as components of the light source drive part 22. The pulse generation circuit 36 may be incorporated in the controller 21.

The electric storage element 33 is composed of a capacitor and is connected to the DC power supply 31 via the resistor 32. The electric storage element 33 may be composed of a single capacitor or may be composed of a plurality of capacitors connected in parallel. Electric charge is accumulated in the electric storage element 33 according to the time constant of a circuit including the resistor 32 and the electric storage element 33. The electric storage element 33 supplies a drive current to the laser light source 11 in response to both the switch elements 34a and 34b being made conductive.

As described above, the laser light source 11 is a laser diode. The laser light source 11 emits laser light when the drive current is supplied from the electric storage element 33 thereto. A plurality of laser light sources 11 may be connected in series or connected in parallel between the electric storage element 33 and the switch element 34a to form a light source.

The switch element 34a is switched between a conductive state and a non-conductive state in response to a signal from the driver 35a. The switch element 34b is switched between a conductive state and a non-conductive state in response to a signal from the driver 35b. The switch elements 34a and 34b are, for example, field effect transistors (FETs). The switch elements 34a and 34b may each be composed of another switch element that is switched between a conductive state and a non-conductive state in response to a signal from the driver 35a or

The switch elements 34a and 34b switch the laser light source 11 between a light-emitting state and a non-light-emitting state according to the signals from the drivers 35a and 35b. That is, when the switch elements 34a and 34b are both brought into a conductive state, the drive current is supplied from the electric storage element 33 to the laser light source 11, and the laser light source 11 emits light. When at least one of the switch elements 34a and 34b is brought into a non-conductive state, the supply of the drive current to the laser light source 11 is blocked, and the laser light source 11 is turned off.

The drivers 35a and 35b drive the switch elements 34a and 34b, respectively, in response to a pulse signal inputted from the pulse generation circuit 36. The pulse generation circuit 36 outputs a pulse signal having a predetermined time width in response to receiving the control signal for pulsed light emission from the controller 21. The drivers 35a and 35b set the switch elements 34a and 34b to a conductive state during a period corresponding to the time width of the pulse signal.

In the case where the switch elements 34a and 34b are FETs, the drivers 35a and 35b supply the drive signal to the gates of the respective FETs during a period when the pulse signal rises. Accordingly, during the period corresponding to the pulse signal, the switch elements 34a and 34b are brought into a conductive state, and the drive current is supplied to the laser light source 11. Thus, the laser light source 11 emits pulsed light.

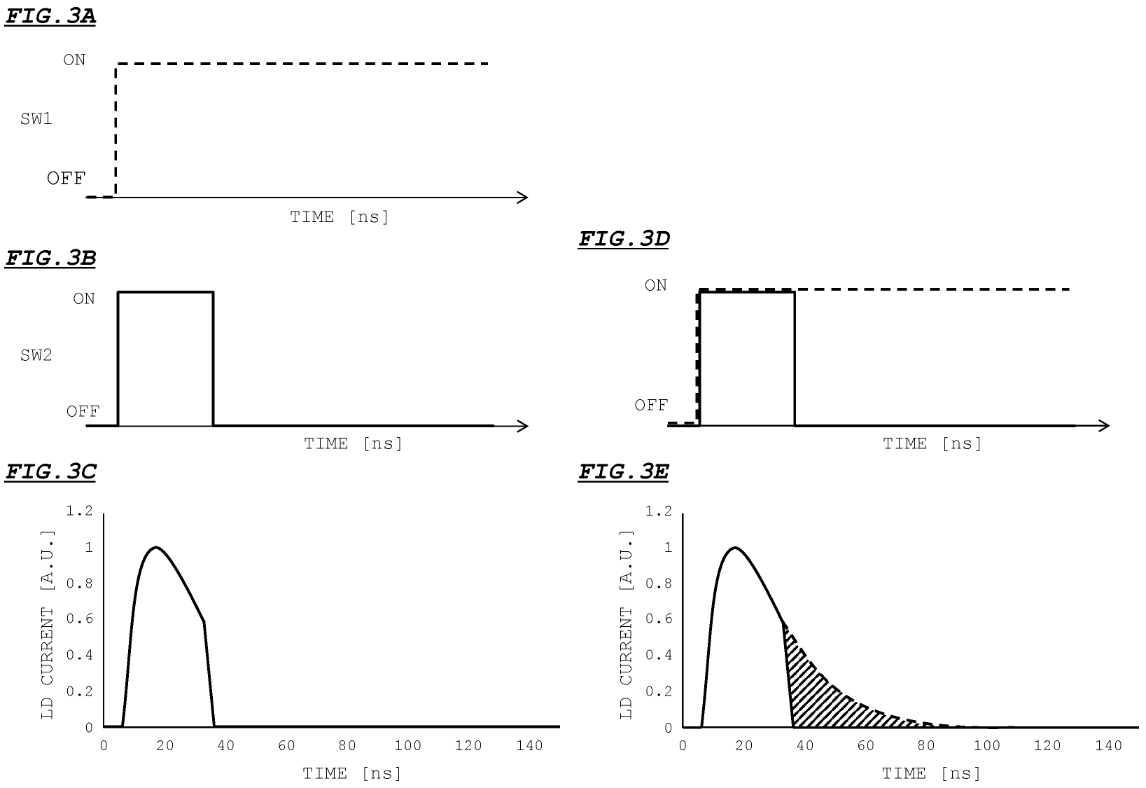

FIG. 3A and FIG. 3B are respectively time charts of the two switch elements 34a and 34b showing ON/OFF states when a short circuit occurs in one of the switch elements 34a and 34b in the configuration of the reference example shown in FIG. 2. Here, in the upstream switch element 34a (SW1) in FIG. 2, a short circuit occurs immediately after a pulsed drive signal is inputted from the driver 35a. The downstream switch element 34b (SW2) is operating normally. FIG. 3C is a time chart showing the drive current of the laser light source 11 in the case of FIG. 3A and FIG. 3B.

As shown in FIG. 3A to FIG. 3C, in the configuration of the reference example, since the two switch elements 34a and 34b are connected in series to the laser light source 11, even if a short circuit occurs in either one of the switch elements (here, the switch element 34a), the other switch element (here, the switch element 34b) opens and closes properly with a time width corresponding to the pulse signal inputted from the pulse generation circuit 36. Accordingly, the time width of the drive current of the laser light source 11 is maintained at a regular time width.

FIG. 3D is a time chart showing an ON/OFF state of a switch element when a short circuit occurs in the switch element, according to a comparative example. FIG. 3E is a time chart showing the drive current of the laser light source 11 in the case of FIG. 3D.

In the comparative example, only one switch element is placed between the laser light source 11 and a ground. That is, in the comparative example, for example, the downstream switch element 34b and the driver 35b are omitted from the configuration in FIG. 2.

In FIG. 3D, a solid line indicates an open/close state of the switch element when no short circuit occurs in the switch element in the configuration of the comparative example. In FIG. 3E, a solid line indicates the drive current of the laser light source 11 in this case. In this case, the switch element opens and closes properly with a time width corresponding to the pulse signal inputted from the pulse generation circuit 36. Accordingly, the time width of the drive current of the laser light source 11 is maintained at the regular time width.

In FIG. 3D, a dashed line indicates an open/close state of the switch element when a short circuit occurs in the switch element in the configuration of the comparative example. Here, a short circuit occurs immediately after a pulsed drive signal is inputted from a driver. In FIG. 3E, a dashed line indicates the drive current of the laser light source 11 in this case.

As shown in FIG. 3E, in the configuration of the comparative example, since only one switch element is placed, if a short circuit occurs in the switch element, the switch element is still conductive even after the time width corresponding to the pulse signal inputted from the pulse generation circuit 36. Therefore, the current continues to flow from the electric storage element 33 to the laser light source 11 even after the regular time width. Accordingly, an extra amount of laser light corresponding to the drive current shown by hatching in FIG. 3E is emitted from the laser light source 11. In the configuration of the comparative example, a situation in which the eye-safety criterion is no longer satisfied may occur due to the extra amount of light.

On the other hand, in the configuration of the reference example, since the two switch elements 34a and 34b are placed as described above, even if a short circuit occurs in one switch element, the time width of the drive current of the laser light source 11 is maintained at the regular time width as shown in FIG. 3C. Therefore, even if a short circuit occurs in either one of the switch elements, the laser light source 11 can be caused to emit pulsed light in an appropriate amount of light. Thus, the amount of laser light emitted in one pulsed light emission can be set as high as possible within the range where the eye-safety criterion can be satisfied. In addition, since a short circuit can be prevented by the two switch elements 34a and 34b, the capacity of the electric storage element 33 can be increased, resulting in reducing the voltage value of the DC power supply 31 and reducing the power consumption of the circuit. Accordingly, the distance range where distance measurement is possible can be extended while low power consumption is achieved.

However, in the configuration of the reference example, since the two switch elements are connected in series to the laser light source 11 as shown in FIG. 2, when the switch elements 34a and 34b are opened, a connection portion between the two switch elements 34a and 34b is brought into a floating state. Therefore, noise is more likely to be superimposed on an input part of the switch element on the laser light source side. Therefore, if a time lag occurs between the drive signals (switch opening/closing signals) inputted to these switch elements 34a and 34b, high-level noise is generated in an input part Pa of the switch element 34a on the laser light source 11 side out of these two switch elements 34a and 34b by ringing caused by extra electric charge in the electric storage element 33 being passed back and forth between the electric storage element 33 and the switch element 34b. If this noise exceeds the rating of the switch element 34a, a failure may occur in the switch element 34a.

In the present embodiment, a configuration for further eliminating such problems is provided in the light emission device 2. This configuration will be described below.

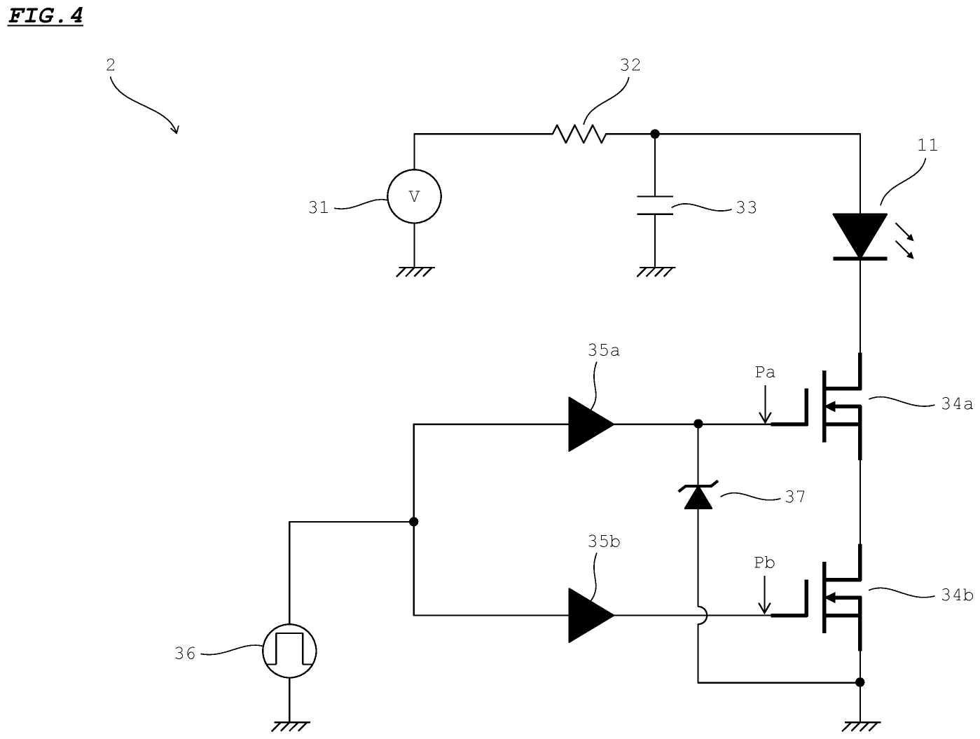

FIG. 4 is a circuit diagram showing a configuration of the light emission device 2 according to Embodiment 1. As in FIG. 2, the controller 21 is not shown in FIG. 4.

As shown in FIG. 4, the light emission device 2 according to Embodiment 1 includes a Zener diode 37 connected between the input part Pa of the upstream switch element 34a and a ground. The Zener diode 37 interrupts the drive signal outputted from the driver 35a, to the ground, and guides noise having a high level exceeding the voltage level of the drive signal, to the ground. The voltage (breakdown voltage or Zener voltage) at which the Zener diode 37 starts conducting is set higher than the voltage level of the drive signal and lower than the rated voltage of the switch element 34a. Accordingly, even if ringing occurs as described above, the switch element 34a can be prevented from failing due to noise having a high voltage level.

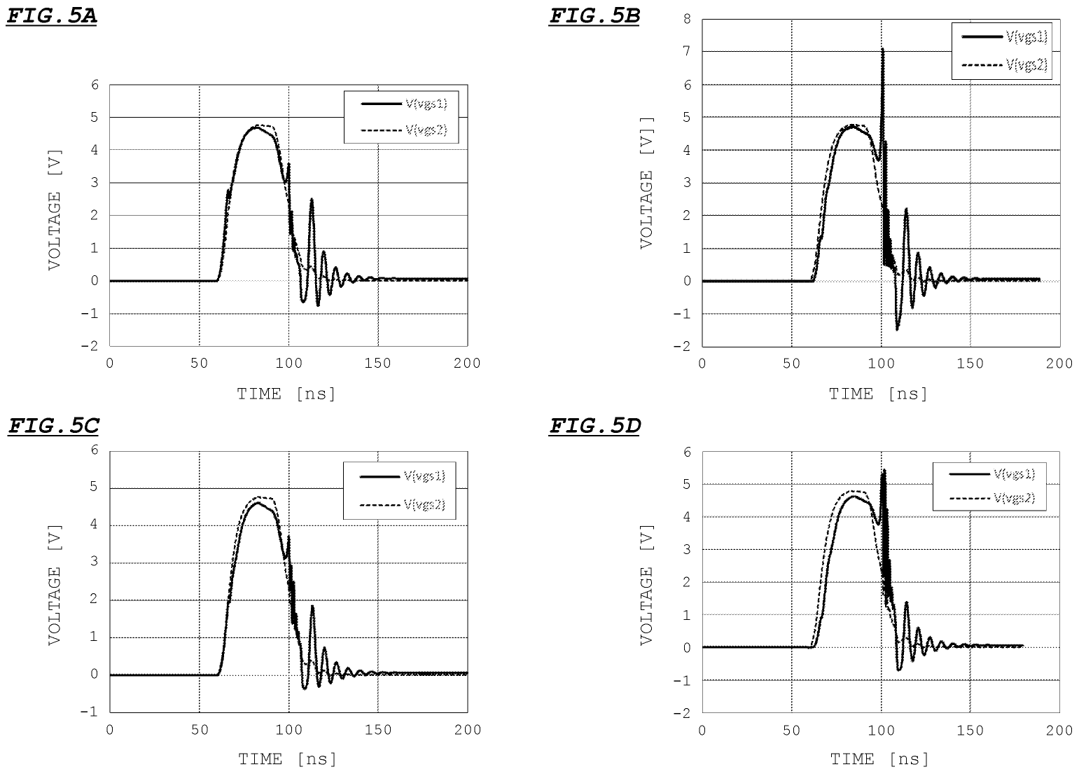

FIG. 5A is a graph showing the simulation results of voltages generated in the input parts Pa and Pb of the respective switch elements 34a and 34b when there is no time lag between the drive signals respectively inputted to the two switch elements 34a and 34b in the configuration of the reference example shown in FIG. 2. FIG. 5B is a graph showing the simulation results of voltages generated in the input parts Pa and Pb of the respective switch elements 34a and 34b when there is a time lag between the drive signals respectively inputted to the two switch elements 34a and 34b in the configuration of the reference example shown in FIG. 2.

In FIG. 5A and FIG. 5B, a solid line indicates the drive signal inputted to the input part Pa of the upstream switch element 34a, and a dashed line indicates the drive signal inputted to the input part Pb of the downstream switch element 34b. The rated voltages of the switch elements 34a and 34b are each 6 V. In FIG. 5B, the drive signal inputted to the input part Pa is delayed by 2 nsec from the drive signal inputted to the input part Pb. The time widths of the respective drive signals are equal to each other.

As shown in FIG. 5A, when no time lag occurs between the drive signals respectively inputted to the input parts Pa and Pb, noise is superimposed on the input part Pa around the end of the drive signal. However, the voltage level of this noise is considerably lower than the rated voltage of the switch element 34a (6 V), and thus this noise does not cause a failure of the switch element 34a.

On the other hand, as shown in FIG. 5B, when a time lag occurs between the drive signals respectively inputted to the input parts Pa and Pb, significantly higher noise is superimposed on the input part Pa around the end of the drive signal than in the case of FIG. 5A. As described above, this noise is due to ringing between the switch element 34b and the electric storage element 33. The voltage level of this noise exceeds the rated voltage of the switch element 34a (6 V). Therefore, this noise may cause a failure of the switch element 34a.

FIG. 5C is a graph showing the simulation results of voltages generated in the input parts Pa and Pb of the respective switch elements 34a and 34b when there is no time lag between the drive signals respectively inputted to the two switch elements 34a and 34b in the configuration of Embodiment 1 shown in FIG. 4. FIG. 5D is a graph showing the simulation results of voltages generated in the input parts Pa and Pb of the respective switch elements 34a and 34b when there is a time lag between the drive signals respectively inputted to the two switch elements 34a and 34b in the configuration of Embodiment 1 shown in FIG. 4.

In FIG. 5C and FIG. 5D, a solid line indicates the drive signal inputted to the input part Pa of the upstream switch element 34a, and a dashed line indicates the drive signal inputted to the input part Pb of the downstream switch element 34b. The rated voltages of the switch elements 34a and 34b are each 6 V. In FIG. 5D, as in FIG. 5B, the drive signal inputted to the input part Pa is delayed by 2 nsec from the drive signal inputted to the input part Pb. The breakdown voltage of the Zener diode 37 shown in FIG. 4 is set to a voltage value (here, 5.1 V) that falls within the range between the maximum value of the drive signal and the rated voltages of the switch elements 34a and 34b (6 V)

As shown in FIG. 5C, when no time lag occurs between the drive signals respectively inputted to the input parts Pa and Pb, noise is superimposed on the input part Pa around the end of the drive signal as in the case of FIG. 5A. However, the voltage level of this noise is considerably lower than the rated voltage of the switch element 34a (6 V), and thus this noise does not cause a failure of the switch element 34a.

As shown in FIG. 5D, when a time lag occurs between the drive signals respectively inputted to the input parts Pa and Pb, higher noise is superimposed on the input part Pa around the end of the drive signal than in the case of FIG. 5C. However, in the configuration of Embodiment 1, due to the action of the Zener diode 37, the maximum voltage level of the noise is reduced to around 5.5 V as compared to the case of the reference example shown in FIG. 5B. Therefore, in the configuration of Embodiment 1, this noise does not cause a failure of the switch element 34a.

As described above, in the configuration of Embodiment 1, since the Zener diode 37 is connected between the input part Pa of the switch element 34a and the ground, noise generated by ringing can be reduced. Accordingly, a failure can be prevented from occurring in the switch element 34a.

### Effects of Embodiment 1

According to Embodiment 1 described above, the following effects can be achieved.

Since the light emission device 2 includes the two switch elements 34a and 34b connected in series to the laser light source 11 as shown in FIG. 4, even if a short circuit occurs in either one of the switch elements, the laser light source 11 can be caused to properly emit pulsed light by the other switch element.

As shown in FIG. 4, the Zener diode 37 (electrical element) which guides, to the ground, high-level noise generated in the input part Pa, to which the drive signal (switch opening/closing signal) is inputted, of the switch element 34a to which the other switch element 34b is connected on the downstream side, is placed. Therefore, as shown in the simulation results in FIG. 5D, high-level noise generated by ringing is guided to the ground, so that noise exceeding the rating can be inhibited from being generated in the input part Pa. Accordingly, a failure can be prevented from occurring in the switch element 34a due to noise.

As described above, in the light emission device 2 of Embodiment 1, pulsed light emission of the laser light source 11 can be performed more properly while failures of the switch elements 34a and 34b are suppressed.

By the very simple configuration in which the Zener diode 37 is connected between the input part Pa and the ground, high-level noise can be inhibited from being generated in the input part Pa, so that a failure of the switch element 34a can be avoided.

Since the distance measurement device 1 includes the light emission device 2 configured as shown in FIG. 4, pulsed light emission of the laser light source 11 can be performed more properly while failures of the switch elements 34a and 34b are suppressed. Thus, the reliability of the distance measurement device 1 can be increased.

As described above, while the voltage of the DC power supply 31 is reduced, the light amount of the laser light source 11 can be set as high as possible within the range where the eye-safety criterion can be satisfied. Thus, while low power consumption is achieved, the distance range were distance measurement is possible can be extended, so that the quality of the distance measurement device 1 can be increased.

### Embodiment 2

In Embodiment 2, a configuration for monitoring drive signals outputted from the drivers 35a and 35b is provided in the light emission device 2.

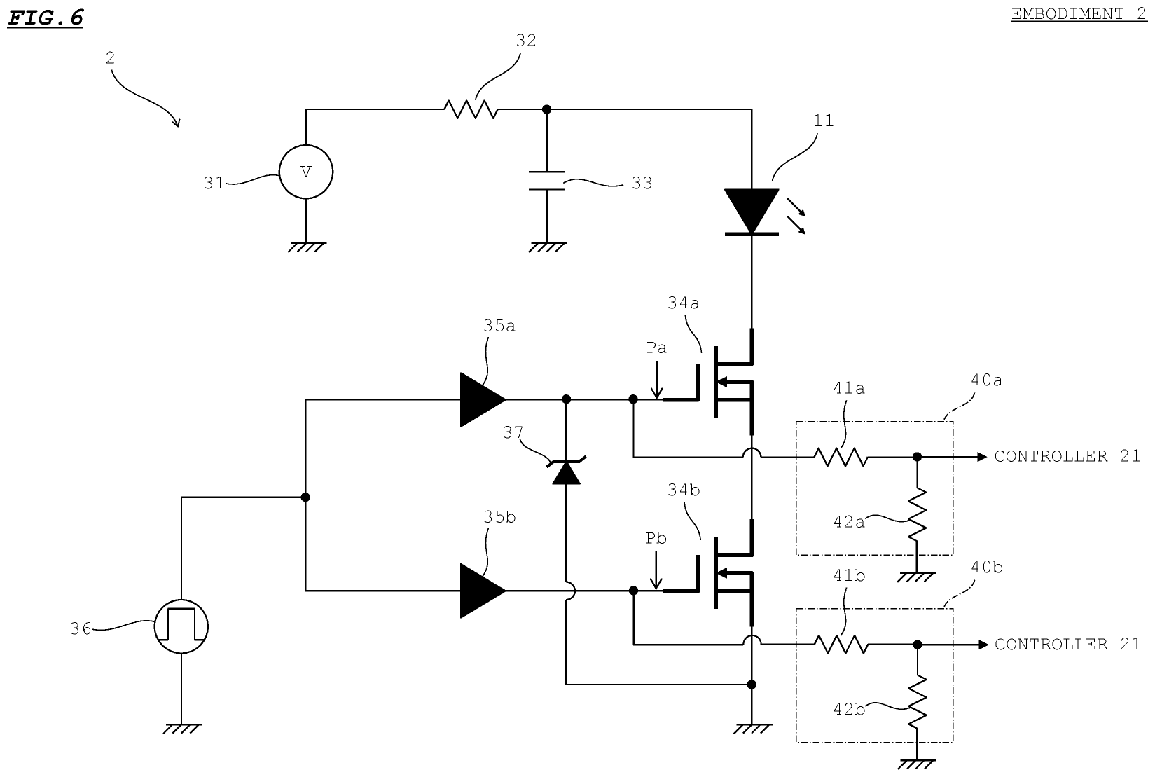

FIG. 6 is a circuit diagram showing a configuration of the light emission device 2 according to Embodiment 2.

The light emission device 2 according to Embodiment 2 further includes monitoring circuits 40a and 40b in addition to the configuration in FIG. 4. The configuration other than the monitoring circuits 40a and 40b is the same as that in FIG. 4.

The monitoring circuit 40a generates a monitoring signal for monitoring the state of the drive signal inputted from the driver 35a to the input part Pa. The monitoring circuit includes two resistors 41a and 42a which divide the drive signal, and outputs the voltage at a connection portion between these resistors 41a and 42a as a monitoring signal. The outputted monitoring signal is supplied to the controller 21.

The monitoring circuit 40b generates a monitoring signal for monitoring the state of the drive signal inputted from the driver 35b to the input part Pb. The monitoring circuit includes two resistors 41b and 42b which divide the drive signal, and outputs the voltage at a connection portion between these resistors 41b and 42b as a monitoring signal. The outputted monitoring signal is supplied to the controller 21.

The resistance values of the resistors 41a and 41b are set to be the same. The resistance values of the resistors 42a and 42b are set to be the same. The resistors 41a and 42a included in the monitoring circuit 40a are set such that the voltage of the monitoring signal does not exceed the operating voltage of the controller 21 (CPU) (e.g., 3.3 V). Similarly, the resistors 41b and 42b included in the monitoring circuit 40b are set such that the voltage of the monitoring signal does not exceed the operating voltage of the controller 21 (CPU) (e.g., 3.3 V). In addition, the resistance values of the resistors 41a and 42a and the resistance values of the resistors 41b and 42b are set to high values such that the voltage levels of the drive signals inputted to the input parts Pa and Pb are appropriately maintained.

The controller 21 determines whether or not the drive signals are appropriate, on the basis of the monitoring signals inputted from the monitoring circuits 40a and 40b, respectively, and detects whether or not the drivers 35a and 35b are operating normally.

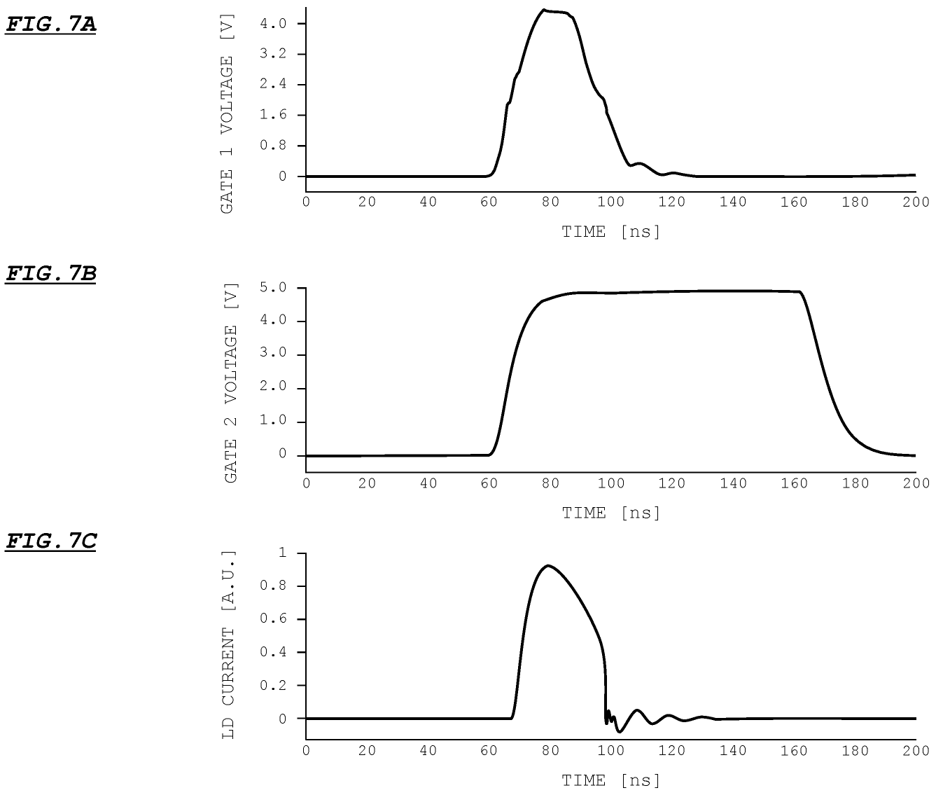

FIG. 7A and FIG. 7B are respectively time charts showing examples of the drive signals inputted to the two switch elements 34a and 34b. FIG. 7C is a time chart showing the drive current of the laser light source 11 in the case of FIG. 7A and FIG. 7B.

FIG. 7A shows the drive signal inputted to the upstream switch element 34a, and FIG. 7B shows the drive signal inputted to the downstream switch element 34b. Here, the period in which the drive signal inputted to the downstream switch element 34b rises is made longer than that in a normal state due to some abnormality. The drive signal inputted to the upstream switch element 34a is normal. In FIG. 7A and FIG. 7B, the vertical axis indicates the voltage value of each drive signal.

In the configuration in FIG. 6, since the two switch elements 34a and 34b are connected in series between the laser light source 11 and a ground as in Embodiment 1 described above, even if an abnormality occurs in one drive signal as shown in FIG. 7B, due to the action of the switch element to which the other drive signal is inputted, a drive current having an appropriate pulse width is supplied to the laser light source 11 as shown in FIG. 7C. Accordingly, the laser light source 11 properly emits pulsed light.

However, in the example in FIG. 7B, it is assumed that a failure has occurred in the downstream driver 35b, and if the operation is continued in this state, when a failure occurs in the upstream driver 35b or the upstream switch element 34a, there is a concern that pulsed light emission is not performed properly and the eye-safety criterion is no longer satisfied. Therefore, when the state shown in FIG. 7B occurs, it is necessary to perform stop of the light emission, notification of the abnormality, etc.

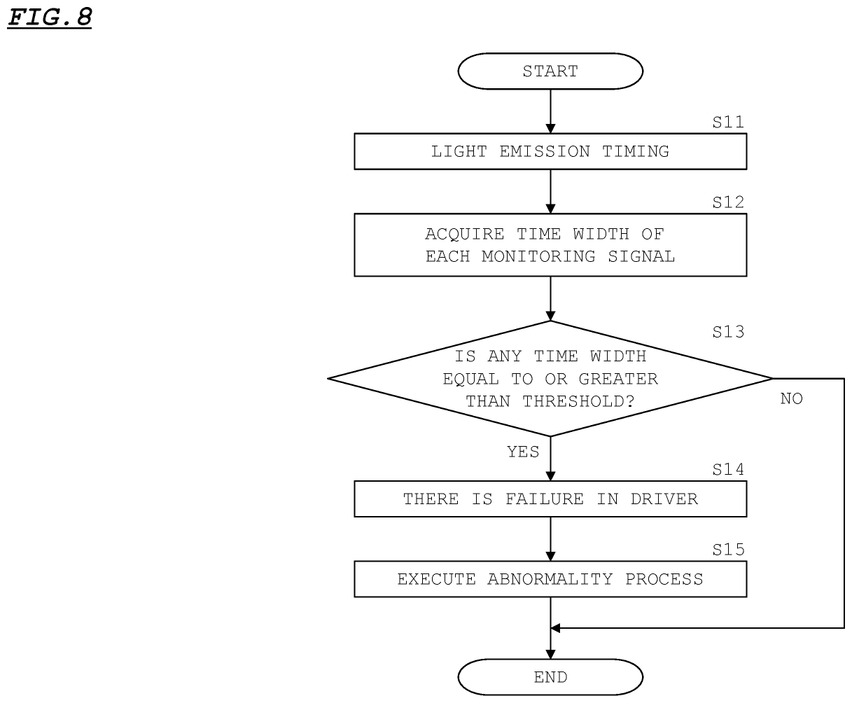

FIG. 8 is a flowchart showing an abnormality detection process for detecting abnormalities in the drivers 35a and 35b (drive signals) on the basis of the monitoring signals generated by the monitoring circuits 40a and 40b.

At the timing of pulsed light emission (S11), the controller 21 acquires a time width in which a monitoring signal is maintained at a predetermined level or higher, for each monitoring signal (S12). Here, the predetermined level is set to a level that is not affected by noise. Next, the controller 21 determines whether or not the acquired time width of each monitoring signal is equal to or greater than a threshold (S13). Here, the threshold is set higher than a specified time width when the monitoring signal is normal, by an allowable width that allows the monitoring signal to be normal.

When none of the time widths is equal to or greater than the threshold (S13: NO), the controller 21 determines that both of the drivers 35a and 35b are normal, and ends the process. On the other hand, when at least one of the time widths is equal to or greater than the threshold (S13: YES), the controller 21 determines that a failure has occurred in at least one of the drivers 35a and 35b (S14), and executes an abnormality process (S15).

In step S15, for example, the controller 21 stops outputting the control signal to the pulse generation circuit 36 to stop the pulsed light emission. Alternatively, the controller 21 outputs a notification that an abnormality has occurred in the driver 35a or 35b, to an external device (device on the vehicle side, or the like), thereby notifying the abnormality to the outside.

In steps S13 and S14, the controller 21 may further detect whether a failure has occurred in any driver, on the basis of whether or not any monitoring signal is equal to or greater than a threshold. In this case, the controller 21 may further output information identifying the driver in which a failure has been detected, to the external device, thereby notifying the information to the outside.

In the case where the operating clock of the controller 21 (CPU) is 500 MHz, the resolution of the time width is 2 nsec. In this case, if an allowable width of about 5 LSB is assumed for the regular time width, the threshold in step S13 is set wider than the regular time width by 10 nsec. Therefore, in this case, a driver failure can be detected when the drive signal extends wider than the regular time width by 10 nsec or more.

### Effects of Embodiment 2

As shown in FIG. 6, the light emission device 2 includes the two switch elements 34a and 34b and the Zener diode 37. Therefore, as in Embodiment 1 described above, pulsed light emission of the laser light source 11 can be performed more properly while failures of the switch elements 34a and 34b are suppressed.

A failure of the driver 35a or 35b (a drive signal abnormality) is detected on the basis of the monitoring signals outputted from the monitoring circuits 40a and 40b, respectively, and the abnormality process is performed. Accordingly, occurrence of an abnormality in the pulsed light emission of the laser light source 11 due to a failure of the driver 35a or 35b can be prevented. Therefore, pulsed light emission can be performed properly while the eye-safety criterion is more reliably satisfied.

### Embodiment 3

In Embodiment 2 described above, the monitoring circuits 40a and 40b for detecting failures of the drivers 35a and 35b (drive signal abnormalities) are placed in the light emission device 2. On the other hand, in Embodiment 3, a monitoring circuit for detecting failures of the switch elements 34a and 34b is placed in the light emission device 2.

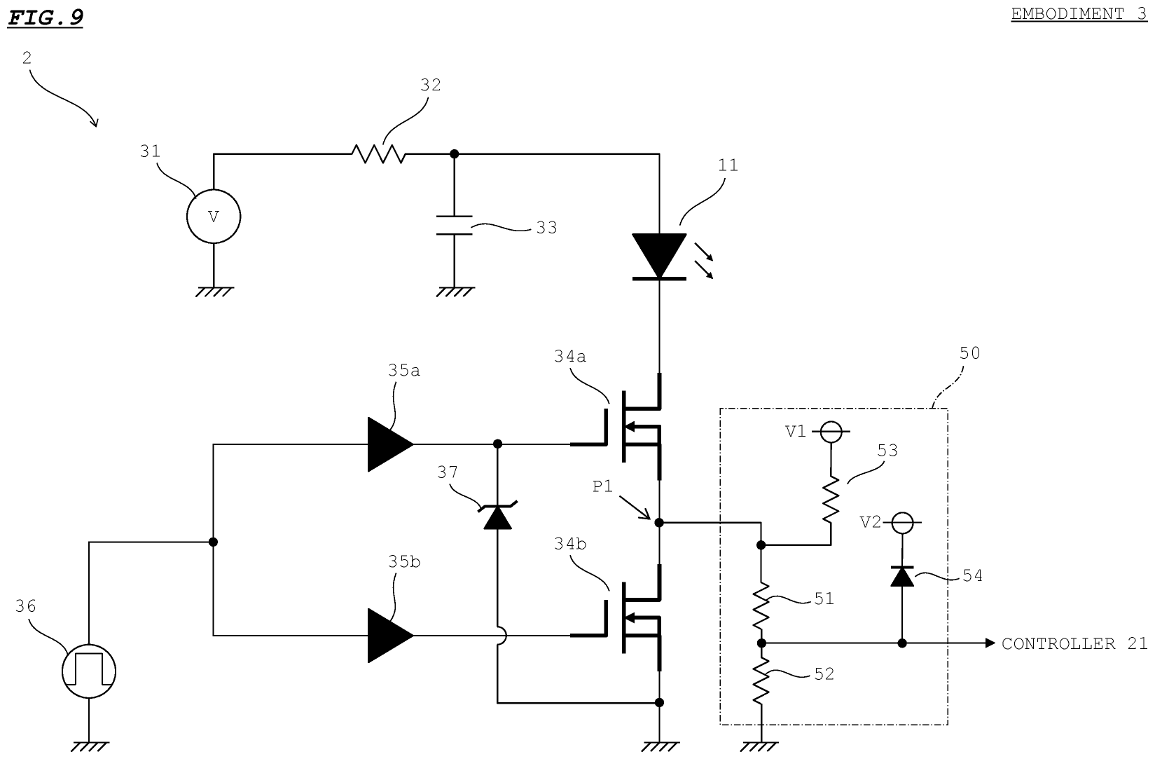

FIG. 9 is a circuit diagram showing a configuration of the light emission device 2 according to Embodiment 3.

The light emission device 2 according to Embodiment 3 further includes a monitoring circuit 50 in addition to the configuration in FIG. 4. The configuration other than the monitoring circuit 50 is the same as that in FIG. 4.

The monitoring circuit 50 monitors failures of the switch elements 34a and 34b on the basis of the potential at a connection portion P1 between the adjacent switch elements 34a and 34b. The monitoring circuit 50 includes two resistors 51 and 52 which divide the potential at the connection portion P1, and outputs the potential at a connection portion between these resistors 51 and 52 as a monitoring signal. The outputted monitoring signal is supplied to the controller 21.

The potential at the connection portion P1 is pulled up to a potential V1 via a resistor 53. The potential V1 is set to about 5 V, for example. In addition, the connection portion between the resistors 51 and 52 is connected to a voltage line of a potential V2 via a diode 54. The potential V2 is set to the operating voltage of the controller 21 (CPU) (e.g., 3.3 V). The diode 54 constitutes a protection circuit that protects the controller 21 (CPU) by preventing a voltage (the voltage of external noise or the like) exceeding the operating voltage from being inputted to the controller 21 (CPU).

The resistors 51 and 52 are set such that the voltage of the monitoring signal does not exceed the operating voltage of the controller 21 (CPU). In addition, the resistance values of the resistors 51 and 52 are set to high values such that the drive current of the laser light source 11 is prevented from flowing to the resistors 51 and 52 as much as possible when the switch elements 34a and 34b are in a conductive state. For example, the resistors 51 and 52 are set to 200Ω and 20 kΩ, respectively.

The controller 21 detects whether or not the switch elements 34a and 34b are operating normally, on the basis of the monitoring signal inputted from the monitoring circuit 50.

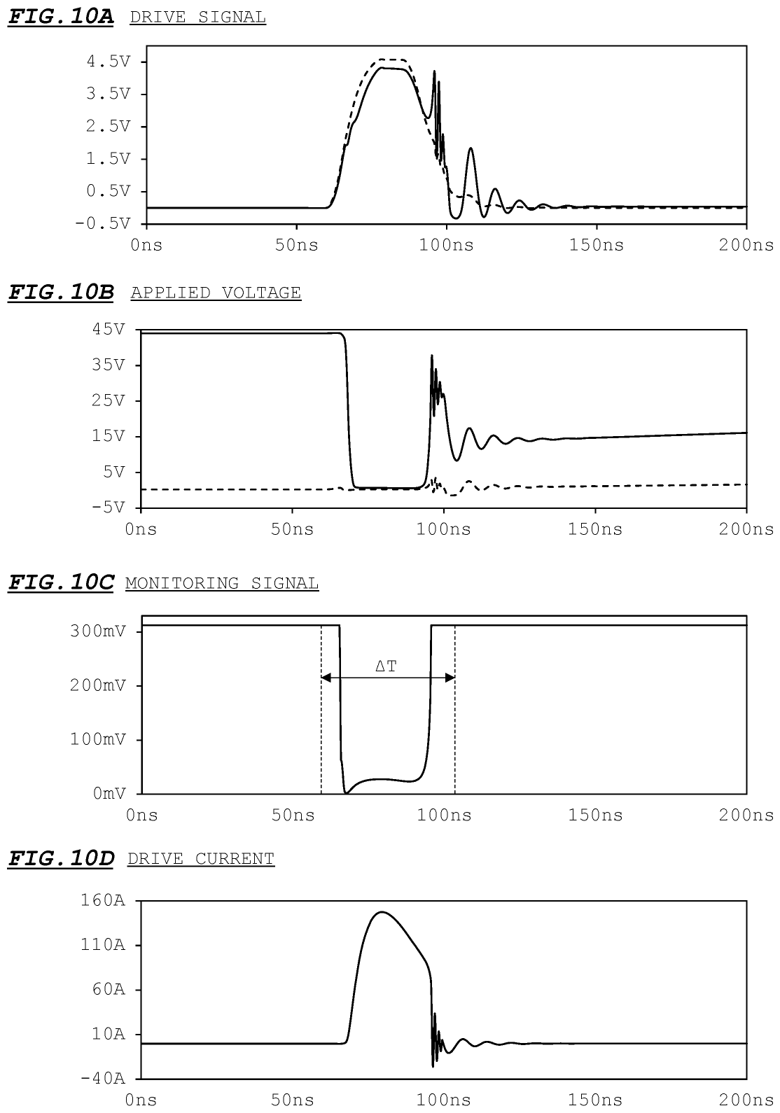

FIG. 10A to FIG. 10D are respectively time charts showing the simulation results of the drive signals, the applied voltages (drain voltages) of the switch elements 34a and 34b, the monitoring signal, and the drive current of the laser light source 11 when the switch elements 34a and 34b are operating normally.

In FIG. 10A, the drive signal inputted to the upstream switch element 34a is indicated by a solid line, and the drive signal inputted to the downstream switch element 34b is indicated by a dashed line. In FIG. 10B, the applied voltage (drain voltage) of the upstream switch element 34a is indicated by a solid line, and the applied voltage (drain voltage) of the downstream switch element 34b is indicated by a dashed line.

In the simulation shown in FIG. 10A to FIG. 10D, the resistors 51, 52, and 53 in the monitoring circuit 50 shown in FIG. 9 are set to 100 kΩ, 200Ω, and 20 kΩ, respectively, and the voltages V1 and V2 are set to 5 V and 3.3 V, respectively. In addition, the breakdown voltage of the Zener diode 37 is set to 5.1 V, and the voltage of the DC power supply 31 is set to 40 V.

As shown in FIG. 10A to FIG. 10D, under the above conditions, even when the monitoring circuit 50 is connected to the connection portion P1, no abnormality occurs in the waveform of the drive current of the laser light source 11, and a drive current having an appropriate time width is obtained.

As shown in FIG. 10C, even when there is no failure in the switch elements 34a and 34b, the monitoring signal fluctuates during a period corresponding to pulsed light emission. Therefore, in order to detect failures of the switch elements 34a and 34b by a simple process without erroneous determination, it is preferable to set a mask period ΔT in a period including the period of pulsed light emission, and perform detection of failures of the switch elements 34a and 34b in the period other than the mask period ΔT.

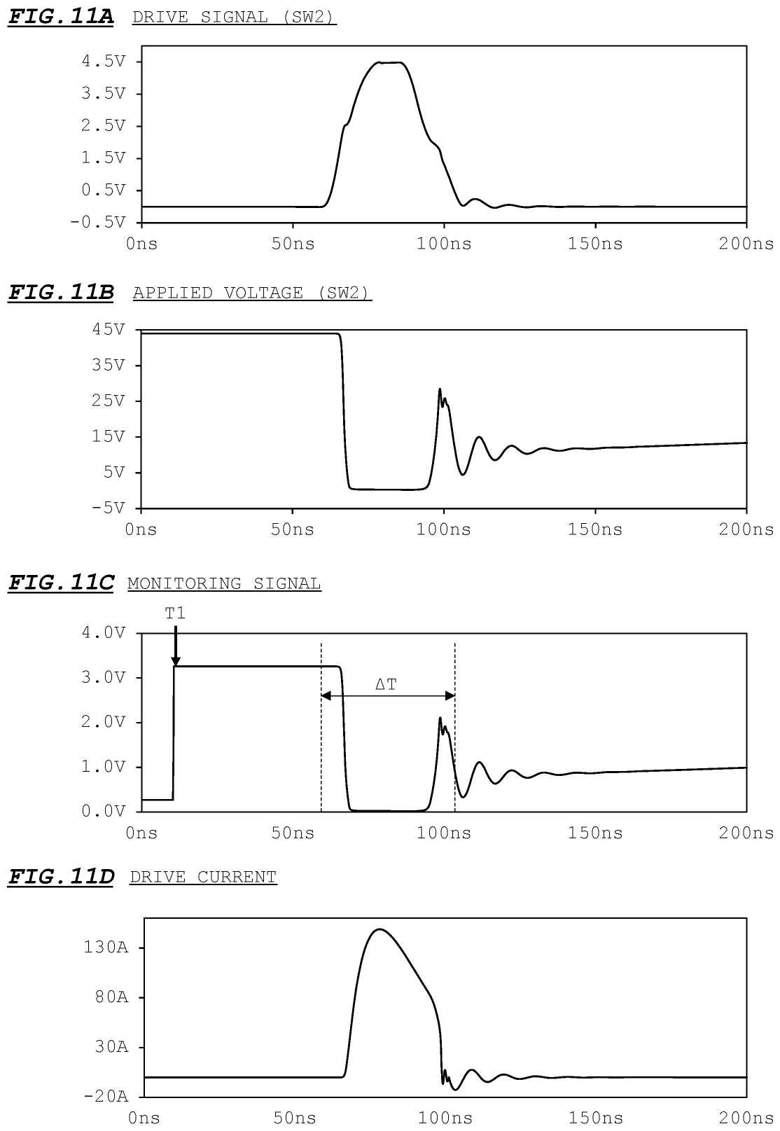

FIG. 11A to FIG. 11D are respectively time charts showing the simulation results of the drive signal of the downstream switch element 34b, the applied voltage (drain voltage) of the downstream switch element 34b, the monitoring signal, and the drive current of the laser light source 11 when a short circuit occurs only in the upstream switch element 34a.

The simulation conditions are the same as in the case of FIG. 10A to FIG. 10D. Here, a short circuit occurs in the upstream switch element 34a at time T1 indicated by an arrow in FIG. 11C.

As shown in FIG. 11A to FIG. 11D, even when a short circuit occurs in the upstream switch element 34a, a drive current of the laser light source 11 having a time width corresponding to the drive signal is obtained due to the action of the downstream switch element 34b. Under the above conditions, even when the monitoring circuit 50 is connected to the connection portion P1, no abnormality occurs in the waveform of the drive current of the laser light source 11, and a drive current having an appropriate time width is obtained.

As shown in FIG. 11C, the monitoring signal is increased sharply from a voltage level in a normal state (around 300 mV) shown in FIG. 10C to 3.3 V in response to the short circuit of the upstream switch element 34a. Therefore, by setting a first threshold between the voltage level in a normal state (around 300 mV) and the voltage after the increase (3.3 V) and comparing the first threshold and the monitoring signal, a failure (short circuit) of the upstream switch element 34a can be detected.

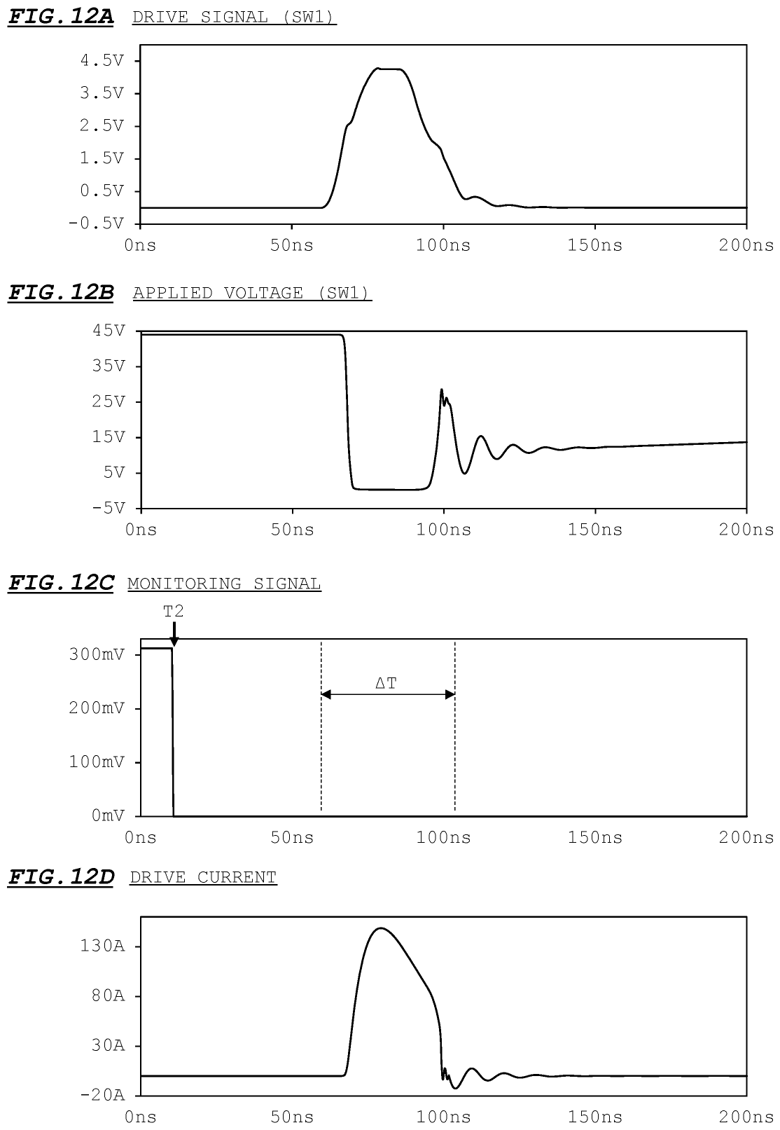

FIG. 12A to FIG. 12D are respectively time charts showing the simulation results of the drive signal of the upstream switch element 34a, the applied voltage (drain voltage) of the upstream switch element 34a, the monitoring signal, and the drive current of the laser light source 11 when a short circuit occurs only in the downstream switch element 34b.

The simulation conditions are the same as in the case of FIG. 10A to FIG. 10D. Here, a short circuit occurs in the downstream switch element 34b at time T2 indicated by an arrow in FIG. 12C.

As shown in FIG. 12A to FIG. 12D, even when a short circuit occurs in the downstream switch element 34b, a drive current of the laser light source 11 having a time width corresponding to the drive signal is obtained due to the action of the upstream switch element 34a. Under the above conditions, even when the monitoring circuit 50 is connected to the connection portion P1, no abnormality occurs in the waveform of the drive current of the laser light source 11, and a drive current having an appropriate time width is obtained.

As shown in FIG. 12C, the monitoring signal is decreased sharply from the voltage level in a normal state (around 300 mV) shown in FIG. 10C to 0 V in response to the short circuit of the downstream switch element 34b. Therefore, by setting a second threshold between the voltage level in a normal state (around 300 mV) and the voltage after the decrease (0 V) and comparing the second threshold and the monitoring signal, a failure (short circuit) of the downstream switch element 34b can be detected.

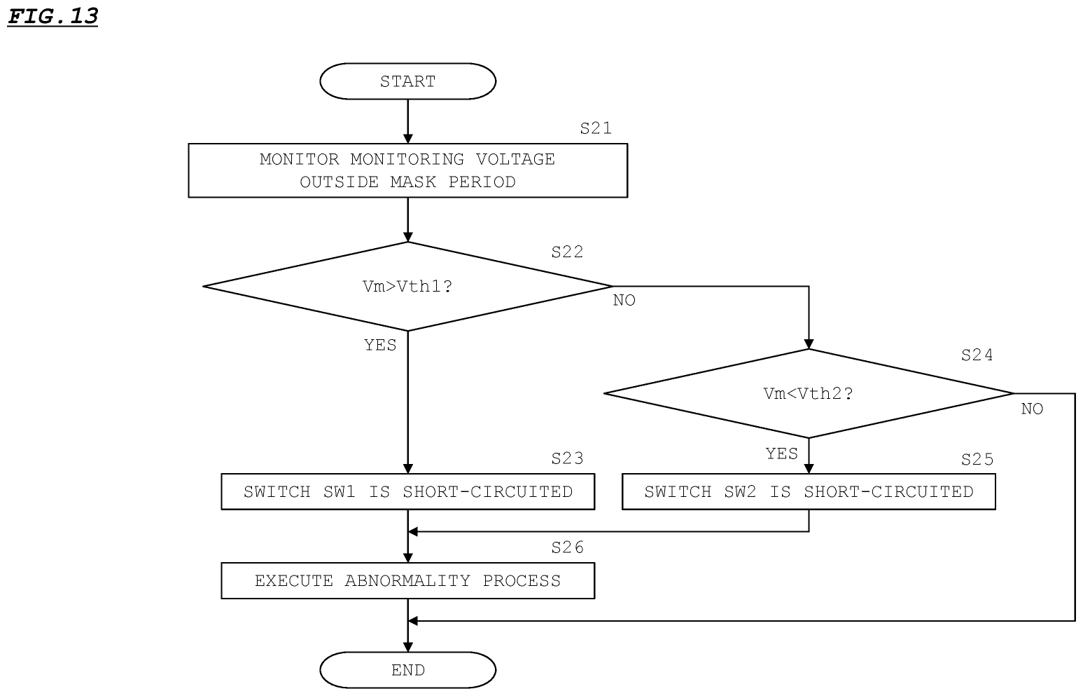

FIG. 13 is a flowchart showing an abnormality detection process for detecting abnormalities of the switch elements 34a and 34b on the basis of the monitoring signal generated by the monitoring circuit 50.

The controller 21 monitors a voltage value Vm of the monitoring signal during the period other than the mask period ΔT (S21). When the voltage value Vm exceeds a first threshold Vth1 (S22: YES), the controller 21 determines that a failure has occurred in the upstream switch element 34a (S23), and executes an abnormality process (S26). As described above, the first threshold Vth1 is set to a voltage value between the voltage value of the monitoring signal generated during the period other than the mask period ΔT during normal operation and the voltage value of the monitoring signal generated when a failure occurs in the switch element 34a. In the example in FIG. 11C, the first threshold Vth1 can be set to around 2 V, for example.

When the voltage value Vm does not exceed the first threshold Vth1 (S22: NO), the controller 21 further determines whether the voltage value Vm is less than the second threshold Vth2 (S24). As described above, the second threshold Vth2 is set to a voltage value between the voltage value of the monitoring signal generated during the period other than the mask period ΔT during normal operation and the voltage value of the monitoring signal generated when a failure occurs in the switch element 34b. In the example in FIG. 12C, the second threshold Vth2 can be set to around 0.15 V, for example.

When the voltage value Vm is not less than the second threshold Vth2 (S24: NO), the controller 21 determines that no failure has occurred in any switch element at this time, and ends the process. In this case, the controller 21 executes the process from step S21 again and monitors failures of the switch elements 34a and 34b. When the voltage value Vm is less than the second threshold Vth2 (S24: YES), the controller 21 determines that a failure has occurred in the downstream switch element 34b (S25), and executes the abnormality process (S26).

In step S26, for example, the controller 21 stops outputting the control signal to the pulse generation circuit 36 to stop the pulsed light emission. Alternatively, the controller 21 outputs a notification that an abnormality has occurred in the switch element 34a or 34b, to an external device (device on the vehicle side, or the like), thereby notifying the abnormality to the outside.

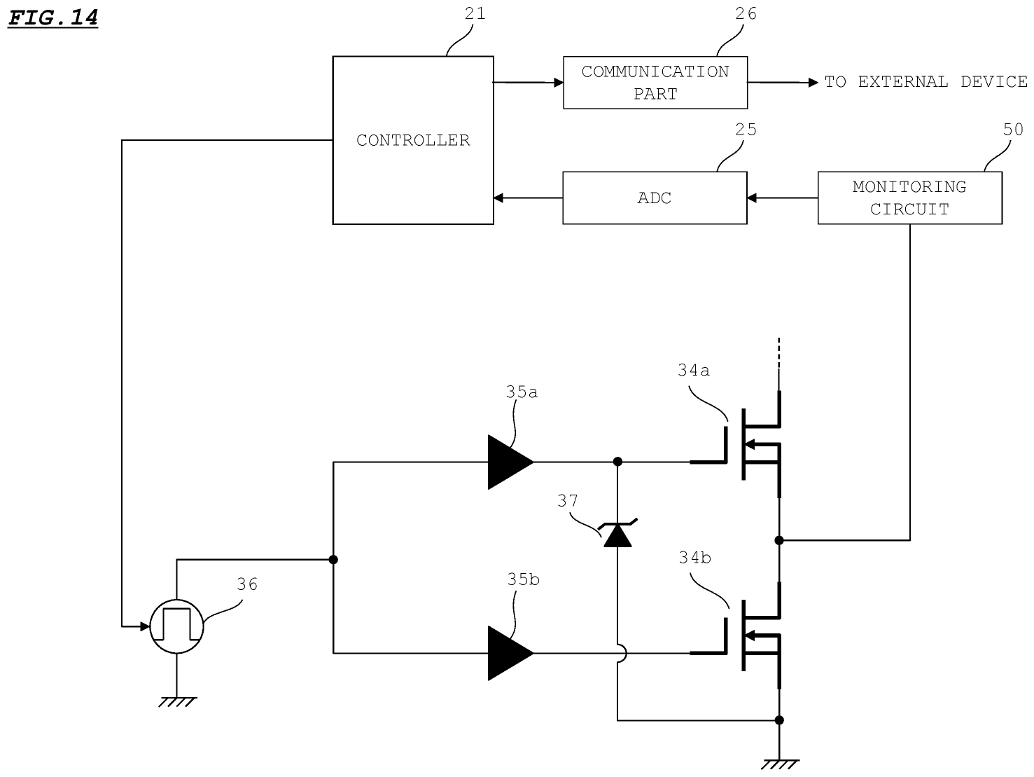

FIG. 14 is a block diagram showing a configuration of the light emission device 2 according to Embodiment 3. For convenience, in FIG. 14, the configuration of the circuitry on the upstream side of the switch element 34a is omitted. The configuration of the circuitry on the upstream side of the switch element 34a is the same as in FIG. 9.

The light emission device 2 further includes an A/D converter (ADC) 25 and a communication part 26 as components of the circuitry in addition to the controller 21 and the monitoring circuit 50.

The ADC 25 samples the monitoring signal (analog signal) inputted from the monitoring circuit 50, at a predetermined sampling frequency to convert the monitoring signal into a digital signal, and outputs the converted digital signal (monitoring signal) to the controller 21. The controller 21 executes the process in FIG. 13 using the monitoring signal (digital signal) inputted from the ADC 25. Then, if the controller 21 detects a failure in any of the switch elements 34a and 34b, the controller 21 stops the operation of the pulse generation circuit 36, and outputs information notifying the abnormality, to the external device via the communication part 26. Accordingly, the external device is notified of the abnormality.

In Embodiment 2 described above, the same configuration as in FIG. 14 may also be applied to the light emission device 2. In this case, the monitoring circuit 50 in FIG. 14 is replaced by the monitoring circuits 40a and 40b, and the monitoring signals outputted from the monitoring circuits 40a and 40b are supplied to the controller 21 via the ADC 25.

### Effects of Embodiment 3

As shown in FIG. 9, the light emission device 2 includes the two switch elements 34a and 34b and the Zener diode 37. Therefore, as in Embodiment 1 described above, pulsed light emission of the laser light source 11 can be performed more properly while failures of the switch elements 34a and 34b are suppressed.

A failure of the switch element 34a or 34b is detected on the basis of the monitoring signal outputted from the monitoring circuit 50, and the abnormality process is performed. Accordingly, occurrence of an abnormality in the pulsed light emission of the laser light source 11 due to a failure of the switch element 34a or 34b can be prevented. Therefore, pulsed light emission can be performed properly while the eye-safety criterion is more reliably satisfied.

The monitoring circuit 50 monitors failures of the switch elements 34a and 34b on the basis of the potential at the connection portion P1 between the adjacent switch elements 34a and 34b. Specifically, the monitoring circuit 50 includes the voltage-dividing resistors 51 and 52 placed between the connection portion P1 and the ground, and outputs the voltage divided by the voltage-dividing resistors 51 and 52 as a monitoring signal while supplying a voltage having a predetermined level V1 to the connection portion P1. Accordingly, as shown in FIG. 11A to FIG. 12D, failures of the switch elements 34a and 34b can be more properly detected on the basis of the monitoring signal.

As shown in FIG. 13, during the period other than the pulsed light emission period (mask period ΔT), the controller 21 performs control based on the monitoring results of the monitoring circuit 50. By excluding the mask period ΔT, during which the monitoring signal fluctuates when the switch elements 34a and 34b are normal, from the monitoring target as described above, failures of the switch elements 34a and 34b can be detected accurately by a simple determination process.

### Modification of Embodiment 3

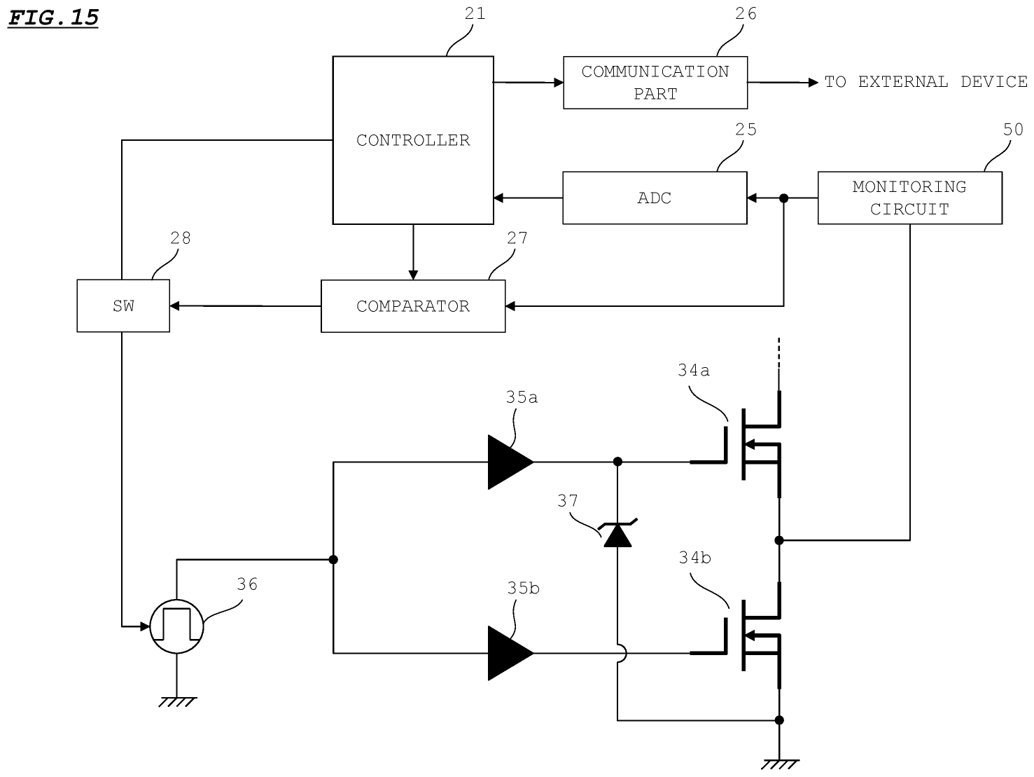

The configuration of the circuitry shown in FIG. 14 may be changed as shown in FIG. 15.

In the configuration in FIG. 15, a comparator 27 and a switch 28 are added to the configuration in FIG. 14. The comparator 27 includes a comparison circuit and a logic circuit, and executes the same processes as in steps S22 and S24 in FIG. 13 on the monitoring signal (analog signal) inputted from the monitoring circuit 50. The comparator 27 outputs a detection signal to the switch 28 when the monitoring signal is greater than the first threshold Vth1 or when the monitoring signal is less than the second threshold Vth2. Accordingly, the switch 28 is opened, and the operation of the pulse generation circuit 36 is stopped. At this time, the controller 21 sets the comparator 27 to a non-operating state during the above-described mask period ΔT. Therefore, during the mask period ΔT, no detection signal is inputted from the comparator 27 to the switch 28.

In this configuration, since the switch 28 is opened by analog processing, when a failure occurs in at least either one of the switch elements 34a and 34b, the pulse generation circuit 36 can be stopped more quickly than in the configuration in FIG. 14. Therefore, the laser light source 11 can be more reliably prevented from emitting pulsed light in an inappropriate light-emitting state.

The position at which the switch 28 is placed is not limited to the position in FIG. 15, and may be another position as long as the pulsed light emission of the laser light source 11 can be stopped when a failure occurs in the switch element 34a or 34b. For example, the switch 28 may be placed between the pulse generation circuit 36 and the drivers 35a and 35b.

In the process in FIG. 13, during the whole period other than the mask period ΔT, the determinations in steps S22 and S24 are performed. However, these determinations may not necessarily be performed during the whole period other than the mask period ΔT, and the determinations in steps S22 and S24 may be performed during a period corresponding to a predetermined timing in the period other than the mask period ΔT.

### Other Modifications

The configurations of the light emission device 2 and the distance measurement device 1 can be modified in various ways other than the configurations shown in Embodiments 1 to 3 described above.

For example, in Embodiments 1 to 3 described above, the two switch elements 34a and 34b are connected in series to the laser light source 11. However, three or more switch elements may be connected in series to the laser light source 11. In this case, the circuit scale increases with the increase in the number of switch elements, but malfunction of the laser light source 11 due to a short circuit of any switch element can be more reliably prevented.

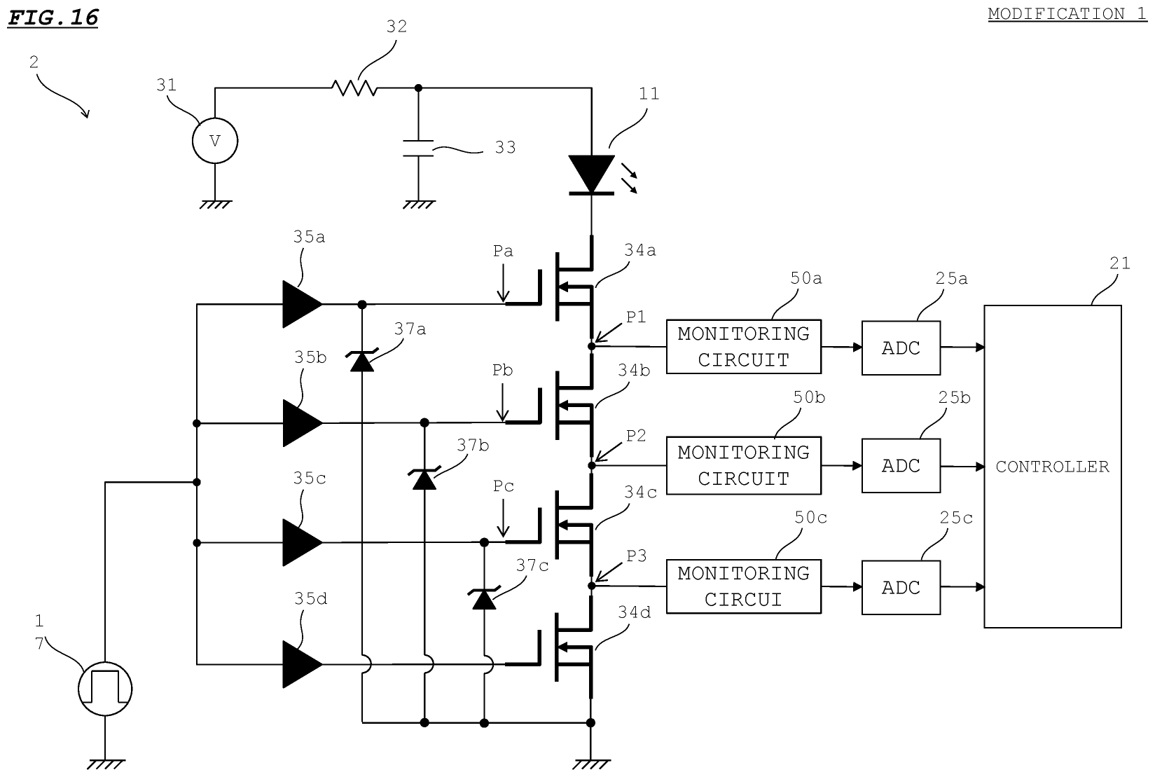

In this case, the monitoring circuit 50 shown in Embodiment 3 described above may be placed at a connection portion between adjacent switch elements. For example, as shown in FIG. 16, in the case where four switch elements 34a to 34d are placed between the laser light source 11 and the ground, monitoring circuits 50a to 50c and ADCs 25a to 25c may be placed at three connection portions P1 to P3, respectively. The configurations of the monitoring circuits 50a to 50c are the same as that of the monitoring circuit 50 shown in Embodiment 3 described above. Also, here, drivers 35a to 35d are individually placed for the four switch elements 34a to 34d.

In this case, Zener diodes 37a to 37c are connected between the ground and input parts Pa to Pc of the switch elements 34a to 34c to each of which another switch element is connected on the ground side, respectively. Accordingly, as in Embodiments 1 to 3 described above, when a time lag occurs between drive signals, occurrence of failures in the switch elements 34a to 34c due to high-level noise generated in the input parts Pa to Pc can be suppressed.

The monitoring circuit does not have to be placed at each of the connection portions P1 to P3 as shown in FIG. 16. For example, the monitoring circuit 50a may be placed only at the connection portion P1, and the monitoring circuits 50b and 50c at the other connection portions P2 and P3 may be omitted. In this case, the monitoring signal outputted from the monitoring circuit 50a is brought into the state in FIG. 11C when a short circuit occurs in the switch element 34a, and is brought into the state in FIG. 12C when all of the switch elements 34b to 34d are short-circuited. In other words, when any one of the switch elements 34b to 34d is normal and a failure occurs in the remaining two switch elements, the monitoring signal is not brought into the state in FIG. 12C.

However, even in this case, it can be at least detected on the basis of the monitoring signal that only one of the four switch elements 34a to 34d is normal and the other three switch elements are in a failed state. Therefore, the pulsed light emission of the laser light source 11 can be stopped before all the switch elements 34a to 34d fail, so that pulsed light emission can be prevented from being performed in a state where the eye-safety criterion is not satisfied.

In the configuration in FIG. 16, which of the switch elements 34a to 34d has failed can be detected from the states of the monitoring signals from the monitoring circuits 50a to 50c. In order to more reliably ensure the reliability of pulsed light emission, it is preferable to increase the number of connection portions P1 to P3 to which the monitoring circuit 50 is applied, as much as possible.

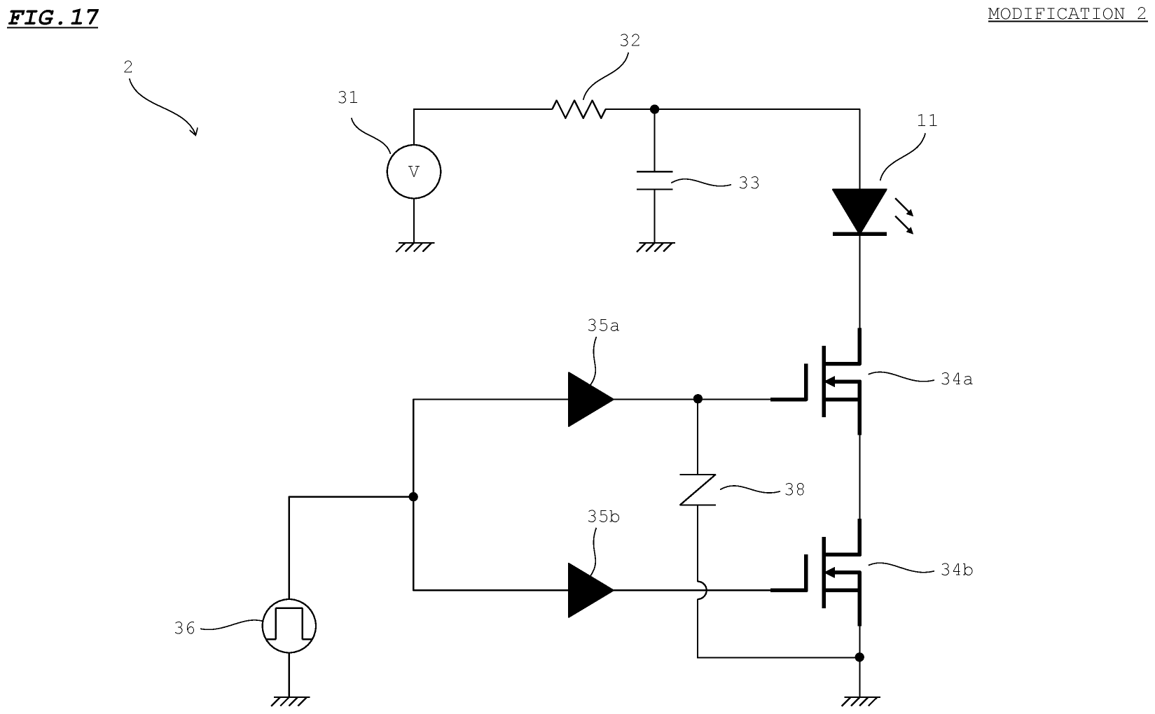

In Embodiments 1 to 3 described above, the Zener diode 37 is used as an electrical element that guides noise having a high level exceeding the voltage level of the drive signal (switch opening/closing signal), to the ground. However, another element may be used as this electrical element. For example, a varistor 38 may be used as this electrical element as shown in FIG. 17. In this case as well, the voltage (varistor voltage) at which the varistor 38 starts conducting is set higher than the voltage level of the drive signal and lower than the rated voltage of the switch element 34a. Accordingly, even if ringing occurs due to a time lag between two drive signals as described above, the switch element 34a can be prevented from failing due to noise having a high voltage level.

In Embodiments 1 to 3 described above, the pulse signal outputted from the one pulse generation circuit 36 is inputted to the two drivers 35a and 35b, but a pulse generation circuit may be placed for each of the drivers 35a and 35b, and a pulse signal may be individually inputted from each pulse generation circuit to each driver. In this case, the two pulse generation circuits are controlled by the controller 21 so as to output pulse signals simultaneously.

In Embodiments 1 to 3 described above, the drivers 35a and 35b are placed for the switch elements 34a and 34b, respectively, but the configuration may be a configuration in which a drive signal outputted from one driver is inputted to the switch elements 34a and 34b.

Both the monitoring circuits 40a and 40b shown in Embodiment 2 and the monitoring circuit 50 shown in Embodiment 3 may be applied to the light emission device 2.

In Embodiments 1 to 3 described above, the electric storage element 33, the laser light source 11, and the switch elements 34a and 34b are placed in this order along the direction in which the drive current flows, but the order of placement is not limited thereto. For example, the electric storage element 33, the switch elements 34a and 34b, and the laser light source 11 may be placed in this order along the direction in which the drive current flows.

In Embodiments 1 to 3 described above, the light emission device 2 is installed in the so-called flash type distance measurement device 1 which simultaneously emits light to the entire distance measurement region A10. However, the present invention is not limited thereto, and the light emission device 2 may be installed in a distance measurement device of a type that performs scanning with a line beam in a short side direction or a distance measurement device of a type that performs scanning with a point beam in a two-dimensional direction.

In addition to the above, various modifications can be made as appropriate to the embodiments of the present invention, without departing from the scope of the technological idea defined by the claims.

What is claimed is:

1. A light emission device comprising:
a laser light source;
an electric storage element for supplying a drive current to the laser light source;
a plurality of switch elements connected in series to the laser light source; and
an electrical element placed at least between a ground and an input part, for a switch opening/closing signal, of the switch element to which another one of the switch elements is connected on a downstream side, and configured to guide noise having a high level exceeding a voltage level of the switch opening/closing signal, to the ground.

2. The light emission device according to claim 1, wherein the electrical element is a Zener diode.

3. The light emission device according to claim 1, wherein the electrical element is a varistor.

4. The light emission device according to claim 1, further comprising a monitoring circuit configured to monitor failures of the switch elements.

5. The light emission device according to claim 4, wherein the monitoring circuit monitors failures of the switch elements on the basis of a potential at a connection portion between the adjacent switch elements.

6. The light emission device according to claim 5, wherein the monitoring circuit includes a voltage-dividing resistor placed between the connection portion and the ground, and outputs a voltage divided by the voltage-dividing resistor as a monitoring signal while supplying a voltage having a predetermined level to the connection portion.

7. The light emission device according to claim 4, further comprising a controller configured to determine failures of the switch elements on the basis of a monitoring result of the monitoring circuit, wherein
the controller performs the determination based on the monitoring result of the monitoring circuit during a predetermined period other than a pulsed light emission period.

8. The light emission device according to claim 1, further comprising a monitoring circuit configured to monitor presence/absence of an abnormality in the switch opening/closing signal inputted to an input part of each of the switch elements.

9. A distance measurement device comprising:
a light emission device;
a projection optical system configured to project pulsed light emitted from the light emission device, to a target region; and
a light receiver configured to receive reflected light, from an object, of the pulsed light, wherein
the light emission device includes
a laser light source,
an electric storage element for supplying a drive current to the laser light source,
a plurality of switch elements connected in series to the laser light source, and
an electrical element placed at least between a ground and an input part, for a switch opening/closing signal, of the switch element to which another one of the switch elements is connected on a downstream side, and configured to guide noise having a high level exceeding a voltage level of the switch opening/closing signal, to the ground.

10. The distance measurement device according to claim 9, wherein the electrical element is a Zener diode.

11. The distance measurement device according to claim 9, wherein the electrical element is a varistor.

12. The distance measurement device according to claim 9, wherein the light emission device includes a monitoring circuit configured to monitor failures of the switch elements.

13. The distance measurement device according to claim 12, wherein the monitoring circuit monitors failures of the switch elements on the basis of a potential at a connection portion between the adjacent switch elements.

14. The distance measurement device according to claim 13, wherein the monitoring circuit includes a voltage-dividing resistor placed between the connection portion and the ground, and outputs a voltage divided by the voltage-dividing resistor as a monitoring signal while supplying a voltage having a predetermined level to the connection portion.

15. The distance measurement device according to claim 12, further comprising a controller configured to determine failures of the switch elements on the basis of a monitoring result of the monitoring circuit, wherein
the controller performs the determination based on the monitoring result of the monitoring circuit during a predetermined period other than a pulsed light emission period.

16. The distance measurement device according to claim 9, wherein the light emission device includes a monitoring circuit configured to monitor presence/absence of an abnormality in the switch opening/closing signal inputted to an input part of each of the switch elements.
